(19) United States
(12) Patent Application Publication
(10) Pub. No.: US 2022/0367800 A1
(43) Pub. Date: Nov. 17, 2022

(54) RESISTIVE MEMORY DEVICE AND METHOD OF MANUFACTURING THE SAME

(71) Applicant: DB HITEK CO., LTD., Seoul (KR)

(72) Inventors: Hyun Chan JO, Seoul (KR); In Hee JANG, Chungcheongbuk-do (KR)

(21) Appl. No.: 17/662,928

(22) Filed: May 11, 2022

(30) Foreign Application Priority Data
May 12, 2021 (KR) 10-2021-0061468

(51) Int. Cl. H01L 45/00; H01L 27/24

(52) U.S. Cl. CPC H01L 45/1246; H01L 27/2436; H01L 45/08; H01L 45/1233; H01L 45/1253; H01L 45/16

(57) ABSTRACT

A resistive memory device and a method of manufacturing the same are disclosed. The resistive memory device includes an insulating layer disposed on a substrate and having a contact hole exposing a surface portion of the substrate, a lower electrode disposed in the contact hole, an adhesive layer disposed between the contact hole and the lower electrode, a first diffusion barrier layer disposed between the adhesive layer and the lower electrode, a second diffusion barrier layer disposed on the insulating layer, the lower electrode, the adhesive layer and the first diffusion barrier layer, a variable resistance layer disposed on the second diffusion barrier layer, and an upper electrode disposed on the variable resistance layer.

### CROSS-REFERENCE TO RELATED APPLICATION

This application claims the priority benefit of Korean Patent Application No. 10-2021-0061468, filed on May 12, 2021, and all the benefits accruing therefrom under 35 U.S.C. § 119, the contents of which are incorporated by reference in their entirety.

### TECHNICAL FIELD

The present disclosure relates to a resistive memory device and a method of manufacturing the same. More specifically, the present disclosure relates to a resistive memory device that may be used as a Resistive Random Access Memory (ReRAM) device by storing data using a resistance state difference of a variable resistance layer, and a method of manufacturing the resistive memory device.

### BACKGROUND

A resistive memory device has a simple device structure and advantages of high operation speed and low power operation. Unlike a flash memory device that stores electric charges, the resistive memory device stores data using a resistance state difference of a variable resistance layer. For example, the resistive memory device may have a high resistance state (HRS) and a low resistance state (LRS). Further, the resistive memory device may have several resistance states according to materials and structures constituting the device.

A switching operation of the resistive memory device may include a forming process in which a conductive filament is formed to become a low resistance state from an initial state, a RESET operation process in which the conductive filament is broken and a resistance of the variable resistance layer is increased, and a SET operation process in which the conductive filament is formed again and the resistance is lowered.

For example, the resistive memory device may be electrically connected to a transistor formed on a substrate. In such case, a contact plug connected to the transistor may be used as a lower electrode, and a variable resistance layer and an upper electrode may be formed on the contact plug. In particular, an insulating layer having a contact hole may be formed on the substrate, and an adhesive layer and a diffusion barrier layer may be formed on an inner side surface of the contact hole and a surface portion of the substrate exposed by the contact hole. As an example, a titanium layer and a titanium nitride layer may be used as the adhesive layer and the diffusion barrier layer.

However, in the case of the resistive memory device having the above structure, a conductive filament may be formed in the variable resistance layer in the forming processor the SET operation process, and the conductive filament may be broken in the RESET operation process. However, metal diffusion may occur from the adhesive layer into the variable resistance layer, whereby a second conductive filament may be formed in the variable resistance layer. In such case, because the second conductive filament is formed by the metal diffusion, it may be maintained without being broken in the RESET operation process. As a result, the RESET operation process of the resistive memory device may not be normally performed due to the second conductive filament.

### SUMMARY

The present disclosure provides a resistive memory device capable of preventing formation of a second conductive filament due to metal diffusion in a variable resistance layer and a method of manufacturing the resistive memory device.

In accordance with an aspect of the present disclosure, a resistive memory device may include an insulating layer disposed on a substrate and having a contact hole exposing a surface portion of the substrate, a lower electrode disposed in the contact hole, an adhesive layer disposed between the contact hole and the lower electrode, a first diffusion barrier layer disposed between the adhesive layer and the lower electrode, a second diffusion barrier layer disposed on the insulating layer, the lower electrode, the adhesive layer and the first diffusion barrier layer, a variable resistance layer disposed on the second diffusion barrier layer, and an upper electrode disposed on the variable resistance layer.

In accordance with some embodiments of the present disclosure, the second diffusion barrier layer may be made of the same material as the first diffusion barrier layer.

In accordance with some embodiments of the present disclosure, the first diffusion barrier layer and the second diffusion barrier layer may be made of metal nitride.

In accordance with some embodiments of the present disclosure, the second diffusion barrier layer may have an opening exposing the lower electrode.

In accordance with some embodiments of the present disclosure, the resistive memory device may further include a third diffusion barrier layer disposed in the opening, and the variable resistance layer may be disposed on the second diffusion barrier layer and the third diffusion barrier layer. In such case, the third diffusion barrier layer may be made of the same material as the first diffusion barrier layer, and the second diffusion barrier layer may be made of a material different from the first diffusion barrier layer. For example, the first diffusion barrier layer and the third diffusion barrier layer may be made of metal nitride, and the second diffusion barrier layer may be made of silicon nitride.

In accordance with some embodiments of the present disclosure, the variable resistance layer may include a first oxide layer disposed on the second diffusion barrier layer, and a second oxide layer disposed on the first oxide layer. In such case, the first oxide layer may have a greater oxygen content than the second oxide layer.

In accordance with some embodiments of the present disclosure, the variable resistance layer may include a first silicon oxide layer disposed on the second diffusion barrier layer, and a second silicon oxide layer disposed on the first silicon oxide layer. In such case, the second silicon oxide layer may have a greater number of oxygen vacancies than the first silicon oxide layer.

In accordance with some embodiments of the present disclosure, an impurity diffusion region may be disposed in a surface portion of the substrate, and a portion of the adhesive layer may be disposed on the impurity diffusion region.

In accordance with some embodiments of the present disclosure, the upper electrode may be made of metal silicide.

In accordance with some embodiments of the present disclosure, the upper electrode may have the same size as the variable resistance layer.

In accordance with another aspect of the present disclosure, a method of a resistive memory device may include forming an insulating layer having a contact hole exposing a surface portion of a substrate on the substrate, forming an adhesive layer on an inner side surface of the contact hole and the surface portion of the substrate exposed by the contact hole, forming a first diffusion barrier layer on the adhesive layer, forming a lower electrode on the first diffusion barrier layer to fill the contact hole, forming a second diffusion barrier layer on the insulating layer, the lower electrode, the adhesive layer and the first diffusion barrier layer, forming a variable resistance layer on the second diffusion barrier layer, and forming an upper electrode on the variable resistance layer.

In accordance with some embodiments of the present disclosure, the first diffusion barrier layer and the second diffusion barrier layer may be made of the same material.

In accordance with some embodiments of the present disclosure, the second diffusion barrier layer may have an opening exposing the lower electrode. In such case, the method may further include forming a third diffusion barrier layer in the opening, and the variable resistance layer may be formed on the second diffusion barrier layer and the third diffusion barrier layer. Further, the third diffusion barrier layer may be made of the same material as the first diffusion barrier layer, and the second diffusion barrier layer may be made of a material different from the first diffusion barrier layer. For example, the first diffusion barrier layer and the third diffusion barrier layer may be made of metal nitride, and the second diffusion barrier layer may be made of silicon nitride.

In accordance with some embodiments of the present disclosure, the forming the variable resistance layer may include forming a first oxide layer on the second diffusion barrier layer, and forming a second oxide layer on the first oxide layer. In such case, the first oxide layer may have a greater oxygen content than the second oxide layer.

In accordance with the embodiments of the present disclosure as described above, metal diffusion from the adhesive layer to the variable resistance layer may be prevented by the second diffusion barrier layer. Accordingly, it is possible to prevent an unwanted second conductive filament from being formed between the adhesive layer and the upper electrode, thereby sufficiently preventing an operation error in the RESET operation of the resistive memory device.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic cross-sectional view illustrating a resistive memory device in accordance with an embodiment of the present disclosure;

FIG. 2 is a schematic cross-sectional view illustrating a resistive memory device in accordance with another embodiment of the present disclosure;

FIGS. 3 to 10 are cross-sectional views illustrating a method of manufacturing the resistive memory device as shown in FIG. 1; and

FIGS. 11 to 13 are cross-sectional views illustrating a method of manufacturing the resistive memory device as shown in FIG. 2.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

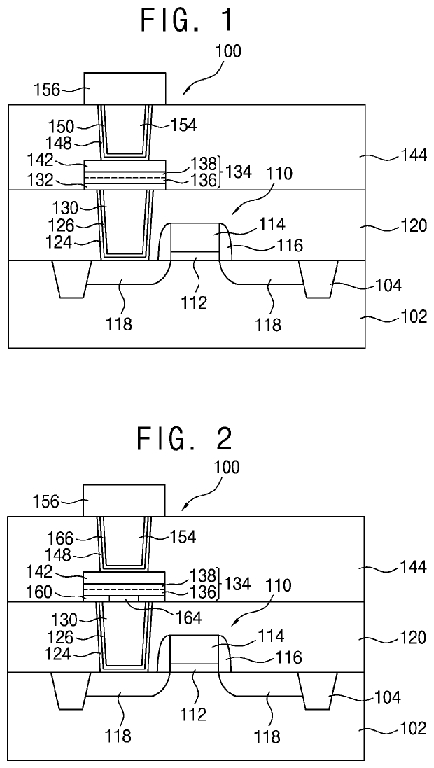

FIG. 1 is a schematic cross-sectional view illustrating a resistive memory device in accordance with an embodiment of the present disclosure.

Referring to FIG. 1, a resistive memory device 100, in accordance with an embodiment of the present disclosure, may include a lower electrode 130 formed on a substrate 102, a variable resistance layer 134 formed on the lower electrode 130, and an upper electrode 142 formed on the variable resistance layer 134. For example, the resistive memory device 100 may include an insulating layer 120 formed on a substrate 102 such as a silicon wafer, and the lower electrode 130 may be formed in the insulating layer 120.

Specifically, an insulating layer 120 having a contact hole 122 (refer to FIG. 4) exposing a surface portion of the substrate 102 may be formed on the substrate 102, and the lower electrode 130 may be formed in the contact hole 122 to be electrically connected to a surface portion of the substrate 102. For example, an adhesive layer 124 may be formed on an inner side surface of the contact hole 122 and the surface portion of the substrate 102 exposed by the contact hole 122, and a first diffusion barrier layer 126 may be formed on the adhesive layer 124. The lower electrode 130 may be formed on the first diffusion barrier layer 126 to fill the contact hole 122. The adhesive layer 124 may be a metal layer, and the first diffusion barrier layer 126 may be a metal nitride layer. For example, the adhesive layer 124 may be a titanium layer, and the first diffusion barrier layer 126 may be a titanium nitride layer.

In accordance with an embodiment of the present disclosure, a second diffusion barrier layer 132 for preventing metal diffusion, that is, titanium diffusion, from the adhesive layer 124 to the variable resistance layer 134 is formed on the insulating layer 120, the lower electrode 130, the adhesive layer 124 and the first diffusion barrier layer 126. The second diffusion barrier layer 132 may be made of the same material as the first diffusion barrier layer 126, for example, titanium nitride. That is, the second diffusion barrier layer 132 may be formed between the adhesive layer 124 and the variable resistance layer 134, and thus, metal diffusion from the adhesive layer 124 to the variable resistance layer 134 may be prevented. As a result, the formation of an unwanted second conductive filament (not shown) in the variable resistance layer 134 by the metal diffusion may be prevented.

The lower electrode 130 may be made of a metal, for example, tungsten or copper. The second diffusion barrier layer 132 may be formed between the lower electrode 130 and the variable resistance layer 134, and thus, metal diffusion from the lower electrode 130 to the variable resistance layer 134 may be prevented. As a result, the formation of a conductive filament (not shown) between the lower electrode 130 and the upper electrode 142 may be precisely controlled.

The variable resistance layer 134 may include a first oxide layer 136 formed on the second diffusion barrier layer 132 and a second oxide layer 138 formed on the first oxide layer 134. In particular, the first oxide layer 136 may have a greater oxygen content than the second oxide layer 138. For example, the first oxide layer 136 may be a first silicon oxide layer, and the second oxide layer 138 may be a second silicon oxide layer. In such case, the second silicon oxide layer 138 may have a smaller oxygen content than the first silicon oxide layer 136, and thus, the second silicon oxide layer 138 may have a greater number of oxygen vacancies than the first silicon oxide layer 136. As described above, the first silicon oxide layer 136 having a relatively high oxygen content and a relatively small number of oxygen vacancies may be formed on the second diffusion barrier layer 132 having a relatively high oxygen affinity, and thus, the RESET operation process of the resistive memory device 100 may be more stably performed.

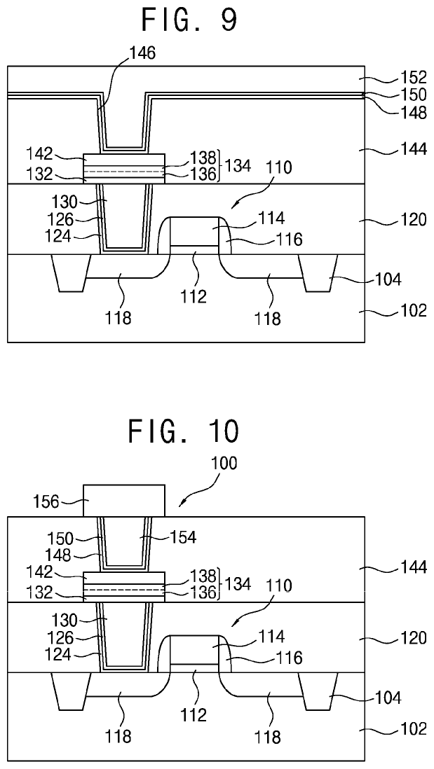

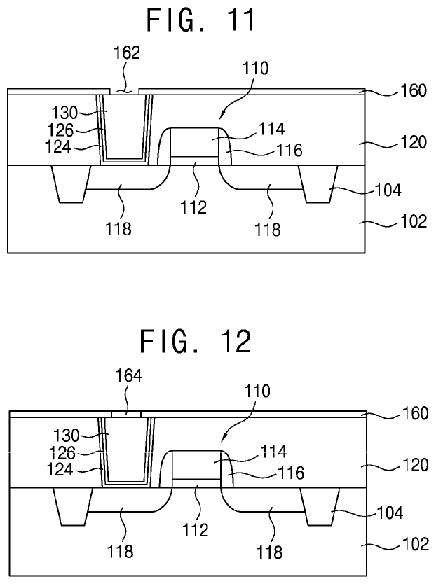

The resistive memory device 100 may include a second insulating layer 144 formed on the insulating layer 120. The second insulating layer 144 may have a second contact hole 146 (refer to FIG. 9) exposing the upper electrode 142. A contact plug 154 may be formed in the second contact hole 146, and a second adhesive layer 148 and a third diffusion barrier layer 150 may be formed between the upper electrode 142 and the contact plug 154. Further, a metal wiring 156 may be formed on the contact plug 154. For example, the contact plug 154 may be made of tungsten or copper, and the metal wiring 156 may be made of aluminum. In addition, a titanium layer and a titanium nitride layer may be used as the second adhesive layer 148 and the third diffusion barrier layer 150.

Meanwhile, a transistor 110 including a gate insulating layer 112, a gate electrode 114, gate spacers 116, and source/drain regions may be formed on the substrate 102. For example, impurity diffusion regions 118 serving as the source/drain regions may be formed in surface regions of the substrate 102, and the lower electrode 130 may be electrically connected to one of the impurity diffusion regions 118. Further, though not shown in FIG. 1, a metal silicide layer (not shown) serving as an ohmic contact may be formed on the surface portions of the impurity diffusion regions 118. As an example, cobalt silicide layers may be formed on surface portions of the impurity diffusion regions 118.

In accordance with an embodiment of the present disclosure, the upper electrode 142 may be made of metal silicide. For example, the upper electrode 142 may be made of tantalum silicide and may have the same size as the variable resistance layer 134 and the second diffusion barrier layer 132.

FIG. 2 is a schematic cross-sectional view illustrating a resistive memory device in accordance with another embodiment of the present disclosure.

Referring to FIG. 2, a resistive memory device 100, in accordance with another embodiment of the present disclosure, may include an insulating layer 120 formed on a substrate 102 and having a contact hole exposing a surface portion of the substrate 102, a lower electrode 130 formed in the contact hole, an adhesive layer 124 formed between the contact hole and the lower electrode 130, a first diffusion barrier layer 126 formed between the adhesive layer 124 and the lower electrode 130, a second diffusion barrier layer 160 formed on the insulating layer 120, the lower electrode 130, the adhesive layer 124 and the first diffusion barrier layer 126, a variable resistance layer 134 formed on the second diffusion barrier layer 160, and an upper electrode 142 formed on the variable resistance layer 134.

A transistor 110 including a gate insulating layer 112 formed on the substrate 102, a gate electrode 114 formed on the gate insulating layer 112, gate spacers 116 formed on side surfaces of the gate electrode 114, and impurity diffusion regions 118 serving as source/drain regions may be formed on the substrate 102, and the lower electrode 130 may be electrically connected to one of the impurity diffusion regions 118. A second insulating layer 144 having a second contact hole exposing the upper electrode 142 may be formed on the insulating layer 120, and a second adhesive layer 148, a fourth diffusion barrier layer 166, and a contact plug 154 may be formed in the second contact hole. Further, a metal wiring 156 may be formed on the contact plug 154.

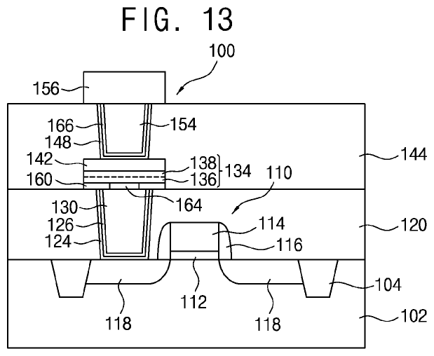

In accordance with another embodiment of the present disclosure, the second diffusion barrier layer 160 may have an opening 162 (refer to FIG. 11) exposing the lower electrode 130, and a third diffusion barrier layer 164 may be formed in the opening 162. In this case, the variable resistance layer 134 may be formed on the second diffusion barrier layer 160 and the third diffusion barrier layer 164. In particular, the third diffusion barrier layer 164 may be made of the same material as the first diffusion barrier layer 126, and the second diffusion barrier layer 160 may be formed of a material different from the first diffusion barrier layer 126. For example, the first diffusion barrier layer 126 and the third diffusion barrier layer 164 may be made of metal nitride, for example, titanium nitride, and the second diffusion barrier layer 160 may be formed of silicon nitride. The second diffusion barrier layer 160 may be used to prevent metal diffusion from the adhesive layer 124 to the variable resistance layer 134, and the third diffusion barrier layer 164 may be used to prevent metal diffusion from the lower electrode 130 to the variable resistance layer 134.

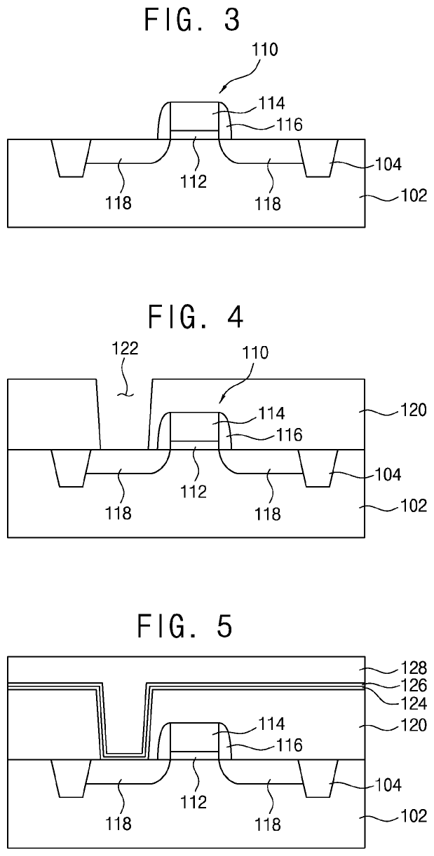

FIGS. 3 to 10 are cross-sectional views illustrating a method of manufacturing the resistive memory device as shown in FIG. 1.

Referring to FIG. 3, device isolation regions 104 for defining an active region may be formed in surface regions of a substrate 102 such as a silicon wafer. For example, the isolation regions 104 may be formed by a shallow trench isolation (STI) process, and may be formed of silicon oxide and/or silicon nitride.

Subsequently, a transistor 110 may be formed in the active region of the substrate 102. For example, a gate insulating layer 112 may be formed on the substrate 102, and a gate electrode 114 may be formed on the gate insulating layer 112. The gate insulating layer 112 may be a silicon oxide layer formed by a thermal oxidation process, and the gate electrode 114 may be formed of polysilicon doped with impurities. In addition, gate spacers 116 may be formed on side surfaces of the gate electrode 114.

Impurity diffusion regions 118 serving as source/drain regions may be formed in surface portions of the substrate 102 adjacent to the gate electrode 114. For example, the impurity diffusion regions 118 may be formed by an ion implantation process and a heat treatment process. In addition, although not shown, ohmic contact regions may be respectively formed on surface portions of the impurity diffusion regions 118. For example, cobalt silicide layers may be formed on surface portions of the impurity diffusion regions 118.

Referring to FIG. 4, an insulating layer 120 such as a silicon oxide layer may be formed on the substrate 102, and then, a contact hole 122 exposing a surface portion of the substrate 102, in particular, one of the impurity diffusion regions 118, may be formed through the insulating layer 120.

Referring to FIG. 5, an adhesive layer 124, for example, a titanium layer may be formed on the insulating layer 120, an inner side surface of the contact hole 122, and the surface portion of the substrate 102 exposed by the contact hole 122, and a first diffusion barrier layer 126, for example, a titanium nitride layer may be formed on the adhesive layer 124. Further, a conductive layer 128, for example, a tungsten layer or a copper layer may be formed on the first diffusion barrier layer 126 to fill the contact hole 122.

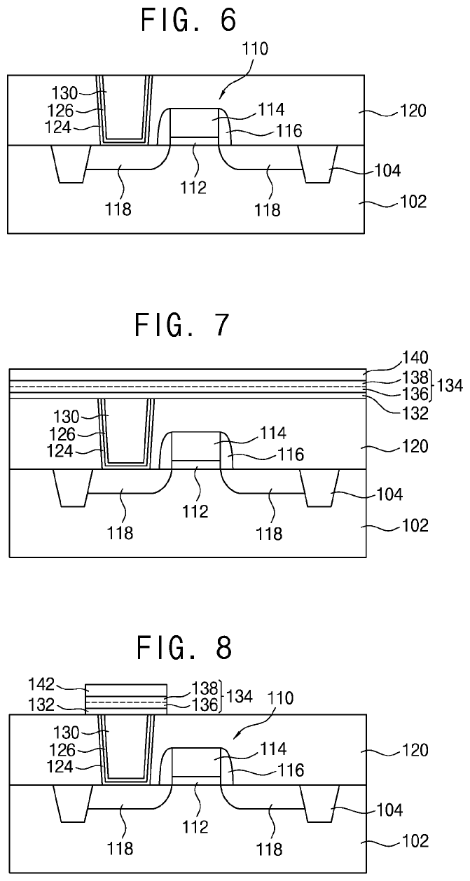

Referring to FIG. 6, the conductive layer 128, the first diffusion barrier layer 126, and the adhesive layer 124 may be partially removed to expose the insulating layer 120, and thus, a lower electrode 130 may be formed in the contact hole 122. For example, the conductive layer 128, the first diffusion barrier layer 126, and the adhesive layer 124 may be partially removed by a chemical mechanical polishing (CMP) process until the insulating layer 120 is exposed. In particular, the adhesive layer 124 and the first diffusion barrier layer 126 may be exposed upwardly by the chemical mechanical polishing process.

Referring to FIG. 7, after forming the lower electrode 130, a second diffusion barrier layer 132, a variable resistance layer 134, and a second conductive layer 140 for forming an upper electrode may be sequentially formed on the insulating layer 120, the lower electrode 130, the exposed adhesive layer 124, and the exposed first diffusion barrier layer 126. For example, a titanium nitride layer functioning as the second diffusion barrier layer 132 and a silicon oxide layer functioning as the variable resistance layer 134 may be formed. In particular, a first silicon oxide layer 136 and a second silicon oxide layer 138 may be sequentially formed on the second diffusion barrier layer 132. The first silicon oxide layer 136 may have a greater oxygen content than the second silicon oxide layer 138, and may have a smaller number of oxygen vacancies than the second silicon oxide layer 138. For example, the first silicon oxide layer 136 and the second silicon oxide layer 138 may be formed by a chemical vapor deposition process or a physical vapor deposition process. A metal silicide layer used as the second conductive layer 140 may be formed on the variable resistance layer 134. For example, a tantalum silicide layer may be formed on the variable resistance layer 134.

Referring to FIG. 8, the second conductive layer 140 may be patterned to form an upper electrode 142. For example, although not shown, after forming a photoresist pattern (not shown) on the second conductive layer 140, the second conductive layer 140 may be patterned by an anisotropic etching process using the photoresist pattern as an etching mask, whereby the upper electrode 142 may be formed on the variable resistance layer 134. Subsequently, the variable resistance layer 134 and the second diffusion barrier layer 132 may be sequentially patterned by the anisotropic etching process using the photoresist pattern. As a result, the variable resistance layer 134 and the second diffusion barrier layer 132 may be patterned to have the same size as that of the upper electrode 142.

Referring to FIG. 9, a second insulating layer 144 such as a silicon oxide layer may be formed on the insulating layer 120 and the upper electrode 142, and then, a second contact hole 146 exposing a surface portion of the upper electrode 142 may be formed through the second insulating layer 144. A second adhesive layer 148 and a third diffusion barrier layer 150 may be formed on the second insulating layer 144, an inner side surface of the second contact hole 146, and the surface portion of the upper electrode 142 exposed by the second contact hole 146. Then, a third conductive layer 152 may be formed on the third diffusion barrier layer 150 to fill the second contact hole 146. For example, a titanium layer and a titanium nitride layer may be formed as the second adhesive layer 148 and the third diffusion barrier layer 150, and a tungsten layer or a copper layer may be formed as the third conductive layer 152.

Referring to FIG. 10, the third conductive layer 152, the third diffusion barrier layer 150, and the second adhesive layer 148 may be partially removed to expose the second insulating layer 144, and thus, a contact plug 154 may be formed in the second contact hole 146. For example, the third conductive layer 152, the third diffusion barrier layer 150, and the second adhesive layer 148 may be partially removed by a chemical mechanical polishing process.

A metal wiring 156 may be formed on the contact plug 154. For example, a metal layer (not shown) such as an aluminum layer may be formed on the second insulating layer 144 and the contact plug 154, and the metal wiring 156 may be formed by patterning the metal layer.

FIGS. 11 to 13 are cross-sectional views illustrating a method of manufacturing the resistive memory device as shown in FIG. 2.

Referring to FIG. 11, after device isolation regions 104 are formed in surface portions of a substrate 102, a transistor 110 including a gate insulating layer 112, a gate electrode 114, and impurity diffusion regions 118 may be formed. Subsequently, an insulating layer 120 having a contact hole exposing any one of the impurity diffusion regions 118 may be formed on the substrate 102, and an adhesive layer 124, a first diffusion barrier layer 126, and a lower electrode 130 may be formed in the contact hole. A method of forming the adhesive layer 124, the first diffusion barrier layer 126, and the lower electrode 130 is substantially the same as described above with reference to FIGS. 3 to 6. Therefore, additional detailed descriptions thereof will be omitted.

After forming the lower electrode 130, a second diffusion barrier layer 160 may be formed on the insulating layer 120, the lower electrode 130, the adhesive layer 124, and the first diffusion barrier layer 126. Then, the second diffusion barrier layer 160 may be partially removed to form an opening 162 exposing the lower electrode 130. For example, the second diffusion barrier layer 160 may be formed of silicon nitride, and the opening 162 may be formed by an anisotropic etching process.

Referring to FIG. 12, a third diffusion barrier layer 164 may be formed in the opening 162. For example, a titanium nitride layer may be formed on the second diffusion barrier layer 160 to fill the opening 162. The third diffusion barrier layer 164 may be formed in the opening 162 by performing a chemical mechanical polishing process until the second diffusion barrier layer 160 is exposed. In this case, the second diffusion barrier layer 160 may function as a stopper layer in the chemical mechanical polishing process.

Referring to FIG. 13, a variable resistance layer 134 and an upper electrode 142 may be formed on the second diffusion barrier layer 160 and the third diffusion barrier layer 164, and a second insulating layer 144 having a second contact hole may be formed on the insulating layer 120 and the upper electrode 142. Then, a second adhesive layer 148, a fourth diffusion barrier layer 166, and a contact plug 154 may be formed in the second contact hole, and a metal wiring 156 may be formed on the contact plug 154. A method of forming the variable resistance layer 134, the upper electrode 142, the second insulating layer 144, the second adhesive layer 148, the fourth diffusion barrier layer 166, the contact plug 154, and the metal wiring 156 is substantially the same as described above with reference to FIGS. 7 to 10. Therefore, additional detailed descriptions thereof will be omitted.

In accordance with the embodiments of the present disclosure as described above, metal diffusion from the adhesive layer 124 to the variable resistance layer 134 may be prevented by the second diffusion barrier layer 132 and 160. Accordingly, it is possible to prevent an unwanted second conductive filament from being formed between the adhesive layer 124 and the upper electrode 142, thereby sufficiently preventing an operation error in the RESET operation of the resistive memory device 100.

Although the example embodiments of the present invention have been described with reference to the specific embodiments, they are not limited thereto. Therefore, it will be readily understood by those skilled in the art that various modifications and changes can be made thereto without departing from the spirit and scope of the present disclosure defined by the appended claims.

1. A resistive memory device comprising:
an insulating layer disposed on a substrate and having a contact hole exposing a surface portion of the substrate;
a lower electrode disposed in the contact hole;
an adhesive layer disposed between a wall of the contact hole and the lower electrode;
a first diffusion barrier layer disposed between the adhesive layer and the lower electrode;
a second diffusion barrier layer disposed on the insulating layer, the lower electrode, the adhesive layer and the first diffusion barrier layer;
a variable resistance layer disposed on the second diffusion barrier layer; and
an upper electrode disposed on the variable resistance layer.

2. The resistive memory device of claim 1, wherein the second diffusion barrier layer is made of a same material as the first diffusion barrier layer.

3. The resistive memory device of claim 2, wherein the first diffusion barrier layer and the second diffusion barrier layer are made of a metal nitride.

4. The resistive memory device of claim 1, wherein the second diffusion barrier layer has an opening exposing the lower electrode.

5. The resistive memory device of claim 4, further comprising a third diffusion barrier layer disposed in the opening,
wherein the variable resistance layer is disposed on the second diffusion barrier layer and the third diffusion barrier layer.

6. The resistive memory device of claim 5, wherein the third diffusion barrier layer is made of a same material as the first diffusion barrier layer, and
the second diffusion barrier layer is made of a material different from the first diffusion barrier layer.

7. The resistive memory device of claim 6, wherein the first diffusion barrier layer and the third diffusion barrier layer are made of metal nitride.

8. The resistive memory device of claim 6, wherein the second diffusion barrier layer is made of a silicon nitride.

9. The resistive memory device of claim 1, wherein the variable resistance layer comprises:
a first oxide layer disposed on the second diffusion barrier layer; and
a second oxide layer disposed on the first oxide layer,
wherein the first oxide layer has an oxygen content that is greater than an oxygen content of the second oxide layer.

10. The resistive memory device of claim 1, wherein the variable resistance layer comprises:
a first silicon oxide layer disposed on the second diffusion barrier layer; and
a second silicon oxide layer disposed on the first silicon oxide layer,
wherein the second silicon oxide layer has a number of oxygen vacancies that is greater than a number of oxygen vacancies of the first silicon oxide layer.

11. The resistive memory device of claim 1, wherein an impurity diffusion region is disposed in a surface portion of the substrate, and
a portion of the adhesive layer is disposed on the impurity diffusion region.

12. The resistive memory device of claim 1, wherein the upper electrode is made of metal silicide.

13. The resistive memory device of claim 1, wherein the upper electrode has a same size as the variable resistance layer.

14. A method of a resistive memory device comprising:
forming an insulating layer having a contact hole exposing a surface portion of a substrate on the substrate;
forming an adhesive layer on an inner side surface of the contact hole and the surface portion of the substrate exposed by the contact hole;
forming a first diffusion barrier layer on the adhesive layer;
forming a lower electrode on the first diffusion barrier layer to fill the contact hole;
forming a second diffusion barrier layer on the insulating layer, the lower electrode, the adhesive layer and the first diffusion barrier layer;
forming a variable resistance layer on the second diffusion barrier layer; and
forming an upper electrode on the variable resistance layer.

15. The method of claim 14, wherein the first diffusion barrier layer and the second diffusion barrier layer are made of a same material.

16. The method of claim 14, wherein the second diffusion barrier layer has an opening exposing the lower electrode.

17. The method of claim 16, further comprising forming a third diffusion barrier layer in the opening,
wherein the variable resistance layer is formed on the second diffusion barrier layer and the third diffusion barrier layer.

18. The method of claim 17, wherein the third diffusion barrier layer is made of a same material as the first diffusion barrier layer, and
the second diffusion barrier layer is made of a material different from the first diffusion barrier layer.

19. The method of claim 18, wherein the first diffusion barrier layer and the third diffusion barrier layer are made of metal nitride, and the second diffusion barrier layer is made of silicon nitride.

20. The method of claim 14, wherein the forming the variable resistance layer comprises:
forming a first oxide layer on the second diffusion barrier layer; and
forming a second oxide layer on the first oxide layer,
wherein the first oxide layer has an oxygen content that is greater than an oxygen content of the second oxide layer.
